(19) United States
(12) Patent Application Publication
(10) Pub. No.: US 2026/0190338 A1
(43) Pub. Date: Jul. 2, 2026

(54) LOGICAL SELECTOR GATE PROGRAMMING

(71) Applicant: Micron Technology, Inc., Boise, ID (US)

(72) Inventors: Masaaki Higuchi, Yokohama (JP); Kenta Yamada, Tokyo (JP); Shuji Tanaka, Kamakura (JP); Kenichiro Nakagawa, Kawasaki (JP); Masashi Yoshida, Yokohama (JP); Jun Fujiki, Boise, ID (US); Yoshiaki Fukuzumi, Yokohama (JP)

(21) Appl. No.: 19/420,476

(22) Filed: Dec. 15, 2025

Related U.S. Application Data
(60) Provisional application No. 63/739,056, filed on Dec. 26, 2024.

(51) Int. Cl. H10B 41/35; H10B 41/27; H10B 43/27; H10B 43/35

(52) U.S. Cl. CPC H10B 41/35; H10B 41/27; H10B 43/27; H10B 43/35

(57) ABSTRACT

Methods, systems, and devices for logical selector gate programming are described. A memory architecture may include a stack of materials that form memory cells at multiple levels in the stack of materials. A portion of the memory cells may be organized into a block that includes a quantity of sub-blocks, each sub-block being independently accessible from other sub-blocks. The memory architecture may include a quantity of bit lines extending through the stack of materials, and a bit line contact coupling a subset of the bit lines with supporting circuitry. In some cases, each bit line of the subset may correspond to a respective sub-block. In some cases, the stack of materials may include one or more levels configured to provide different voltage thresholds for each bit line of the subset, where each bit line of the subset is selectable based on the different voltage thresholds.

### CROSS REFERENCE

The present Application for Patent claims the benefit of U.S. Provisional Patent Application No. 63/739,056 by Higuchi et al., entitled “LOGICAL SELECTOR GATE PROGRAMMING” and Dec. 26, 2024, which is assigned to the assignee hereof and is expressly incorporated by reference in its entirety herein.

### TECHNICAL FIELD

The following relates to one or more systems for memory, including logical selector gate programming.

### BACKGROUND

Memory devices are widely used to store information in various electronic devices such as computers, user devices, wireless communication devices, cameras, digital displays, and the like. Information is stored by programming memory cells within a memory device to various states. For example, binary memory cells may be programmed to one of two supported states, often corresponding to a logic 1 or a logic 0. In some examples, a single memory cell may support more than two possible states, any one of which may be stored by the memory cell. To access information stored by a memory device, a component may read (e.g., sense, detect, retrieve, identify, determine, evaluate) the state of one or more memory cells within the memory device. To store information, a component may write (e.g., program, set, assign) one or more memory cells within the memory device to corresponding states.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), 3-dimensional cross-point memory (3D cross point), not-or (NOR) and not-and (NAND) memory devices, and others. Memory devices may be described in terms of volatile configurations or non-volatile configurations. Volatile memory cells (e.g., DRAM) may lose their programmed states over time unless they are periodically refreshed by an external power source. Non-volatile memory cells (e.g., NAND) may maintain their programmed states for extended periods of time even in the absence of an external power source.

### BRIEF DESCRIPTION OF THE DRAWINGS

FIG. 1 shows an example of a memory system that supports logical selector gate programming in accordance with examples as disclosed herein.

FIG. 2 shows an example of a memory architecture that supports logical selector gate programming in accordance with examples as disclosed herein.

FIGS. 3A, 3B, and 3C show examples of logical architectures that support logical selector gate programming in accordance with examples as disclosed herein.

FIG. 4 shows an example of a memory architecture that supports logical selector gate programming in accordance with examples as disclosed herein.

FIGS. 5A, 5B, 5C, 5D, and 5E show examples of memory architectures that support logical selector gate programming in accordance with examples as disclosed herein.

FIGS. 6A, 6B, 6C, 6D, 6E, 6F, and 6G show examples of processing steps that support logical selector gate programming in accordance with examples as disclosed herein.

FIG. 7 shows a flowchart illustrating a method or methods that support logical selector gate programming in accordance with examples as disclosed herein.

### DETAILED DESCRIPTION

Some memory systems (e.g., NAND memory systems) may implement a memory architecture including blocks of memory cells (e.g., NAND memory cells). In some cases, each block may include a quantity of sub-blocks, where each sub-block may be independently addressable. For example, each sub-block may be associated with one or more bit lines, which may be independently operable to access a quantity of respective memory cells associated with the sub-block. In some implementations, as the memory architecture increases in complexity (e.g., memory cell density), the memory system may experience difficulty accessing the sub-blocks. For example, based on the complexity of the memory architecture, the memory system may apply a voltage to a bit line for accessing a sub-block (e.g., the memory cells of a sub-block), however due to the relative granularity of the bit line within the memory architecture, the voltage may not access the sub-block or may access one or more different sub-blocks (e.g., based on voltage interactions between the bit lines). Thus, the memory system implementing the complex memory architecture may experience decreased reliability for performing access operations on the sub-blocks.

In accordance with examples as described herein, a memory system may implement an improved memory architecture, where levels of the memory architecture are configured to have different voltage thresholds that may support improved accessibility of the sub-blocks. For example, the improved memory architecture may implement a stack of materials including levels with different voltage thresholds, such that bit lines associated with the levels may be associated with different voltage thresholds. Implementing different voltage thresholds for the bit lines may improve accessibility for the corresponding sub-blocks, which may support individually accessing the sub-blocks using a logical pattern based on the different voltage thresholds. In some cases, the different voltage thresholds of the levels may be based on forming the stack of materials using improved processes. For example, to create different voltage thresholds of the levels, some levels may be subjected to a doping operation. In other examples, some levels may be replaced with different materials or a different quantity of the respective material. Implementing the improved memory architecture may improve reliability for performing access operations on the sub-blocks, which may increase overall performance of the corresponding memory system.

In addition to applicability in memory systems as described herein, techniques for logical selector gate programming may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by improving reliability for performing access operations on sub-blocks of a memory architecture, which may decrease processing or latency times, improve response times, or otherwise improve user experience, among other benefits.

In addition to applicability in memory systems as described herein, techniques for logical selector gate programming may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving reliability for performing access operations on sub-blocks of a memory architecture, which may enable greater memory cell density and increased connectivity within the memory architecture, among other benefits.

Features of the disclosure are illustrated and described in the context of systems, devices, and circuits. Features of the disclosure are further illustrated and described in the context of logical architectures, memory architectures, processing steps, and flowcharts.

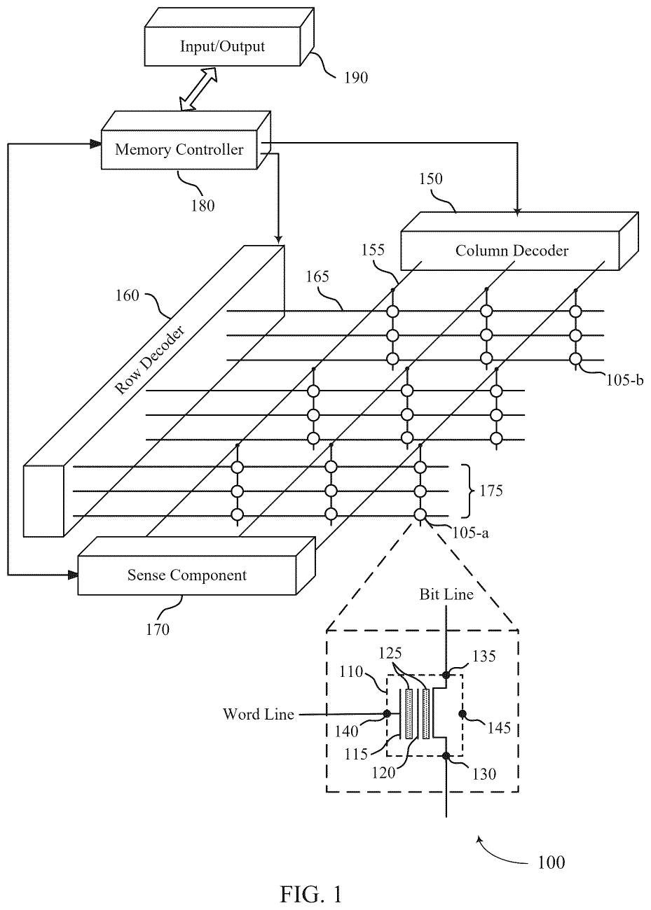

FIG. 1 shows an example of a memory system 100 that supports logical selector gate programming in accordance with examples as disclosed herein. FIG. 1 is an illustrative representation of various components and features of the memory system 100. As such, the components and features of the memory system 100 are shown to illustrate functional interrelationships, and not necessarily physical positions within the memory system 100. Further, although some elements included in FIG. 1 are labeled with a numeric indicator, some other corresponding elements are not labeled, even though they are the same or would be understood to be similar, in an effort to increase visibility and clarity of the depicted features.

The memory system 100 may include one or more memory cells 105, such as memory cell 105-a and memory cell 105-b. In some examples, a memory cell 105 may be a NAND memory cell, such as in the blow-up diagram of memory cell 105-a. Each memory cell 105 may be programmed to store a logic value representing one or more bits of information. In some examples, a single memory cell 105—such as a memory cell 105 configured as a single-level cell (SLC)—may be programmed to one of two supported states and thus may store one bit of information at a time (e.g., a logic 0 or a logic 1). In some other examples, a single memory cell 105—such a memory cell 105 configured as a multi-level cell (MLC), a tri-level cell (TLC), a quad-level cell (QLC), or other type of multiple-level memory cell 105—may be programmed to one state of more than two supported states and thus may store more than one bit of information at a time. In some cases, a multiple-level memory cell 105 (e.g., an MLC memory cell, a TLC memory cell, a QLC memory cell) may be physically different than an SLC cell. For example, a multiple-level memory cell 105 may use a different cell geometry or may be fabricated using different materials. In some examples, a multiple-level memory cell 105 may be physically the same or similar to an SLC cell, and other circuitry in a memory block (e.g., a controller, sense amplifiers, drivers) may be configured to operate (e.g., read and program) the memory cell as an SLC cell, or as an MLC cell, or as a TLC cell, etc.

In some NAND memory arrays, each memory cell 105 may be illustrated as a transistor that includes a charge trapping structure (e.g., a floating gate, a replacement gate, a dielectric material) for storing an amount of charge representative of a logic value. For example, the blow-up in FIG. 1 illustrates a NAND memory cell 105-a that includes a transistor 110 (e.g., a metal-oxide-semiconductor (MOS) transistor) that may be used to store a logic value. The transistor 110 may include a control gate 115 and a charge trapping structure 120 (e.g., a floating gate, a replacement gate), where the charge trapping structure 120 may, in some examples, be between two portions of dielectric material 125. The transistor 110 also may include a first node 130 (e.g., a source or drain) and a second node 135 (e.g., a drain or source). A logic value may be stored in transistor 110 by storing (e.g., writing) a quantity of electrons (e.g., an amount of charge) on the charge trapping structure 120. An amount of charge to be stored on the charge trapping structure 120 may depend on the logic value to be stored. The charge stored on the charge trapping structure 120 may affect the threshold voltage of the transistor 110, thereby affecting the amount of current that flows through the transistor 110 when the transistor 110 is activated (e.g., when a voltage is applied to the control gate 115, when the memory cell 105-a is read). In some examples, the charge trapping structure 120 may be an example of a floating gate or a replacement gate that may be part of a 2D NAND structure. For example, a 2D NAND array may include multiple control gates 115 and charge trapping structures 120 arranged around a single channel (e.g., a horizontal channel, a vertical channel, a columnar channel, a pillar channel).

A logic value stored in the transistor 110 may be sensed (e.g., as part of a read operation) by applying a voltage to the control gate 115 (e.g., to control node 140, via a word line 165) to activate the transistor 110 and measuring (e.g., detecting, sensing) an amount of current that flows through the first node 130 or the second node 135 (e.g., via a bit line 155). For example, a sense component 170 may determine whether an SLC memory cell 105 stores a logic 0 or a logic 1 in a binary manner (e.g., based on a presence or absence of a current through the memory cell 105 when a read voltage is applied to the control gate 115, based on whether the current is above or below a threshold current). For a multiple-level memory cell 105, a sense component 170 may determine a logic value stored in the memory cell 105 based on various intermediate threshold levels of current when a read voltage is applied to the control gate 115, or by applying different read voltages to the control gate and evaluating different resulting levels of current through the transistor 110, or various combinations thereof. In one example of a multiple-level architecture, a sense component 170 may determine the logic value of a TLC memory cell 105 based on eight different levels of current, or ranges of current, that define the eight potential logic values that could be stored by the TLC memory cell 105.

An SLC memory cell 105 may be written by applying one of two voltages (e.g., a voltage above a threshold or a voltage below a threshold) to the memory cell 105 to store, or not store, an electric charge on the charge trapping structure 120 and thereby cause the memory cell 105 to store one of two possible logic values. For example, when a first voltage is applied to the control node 140 (e.g., via a word line 165) relative to a bulk node 145 (e.g., a body node) for the transistor 110 (e.g., when the control node 140 is at a higher voltage than the bulk), electrons may tunnel into the charge trapping structure 120. Injection of electrons into the charge trapping structure 120 may be referred to as programming the memory cell 105 and may occur as part of a write operation. A programmed memory cell may, in some cases, be considered as storing a logic 0. When a second voltage is applied to the control node 140 (e.g., via the word line 165) relative to the bulk node 145 for the transistor 110 (e.g., when the control node 140 is at a lower voltage than the bulk node 145), electrons may leave the charge trapping structure 120. Removal of electrons from the charge trapping structure 120 may be referred to as erasing the memory cell 105 and may occur as part of an erase operation. An erased memory cell may, in some cases, be considered as storing a logic 1. In some cases, memory cells 105 may be programmed at a page level of granularity due to memory cells 105 of a page sharing a common word line 165, and memory cells 105 may be erased at a block level of granularity due to memory cells 105 of a block sharing commonly biased bulk nodes 145.

In contrast to writing an SLC memory cell 105, writing a multiple-level (e.g., MLC, TLC, or QLC) memory cell 105 may involve applying different voltages to the memory cell 105 (e.g., to the control node 140 or bulk node 145 thereof) at a finer level of granularity to more finely control the amount of charge stored on the charge trapping structure 120, thereby enabling a larger set of logic values to be represented. Thus, multiple-level memory cells 105 may provide greater density of storage relative to SLC memory cells 105 but may, in some cases, involve narrower read or write margins or greater complexities for supporting circuitry.

A charge-trapping NAND memory cell 105 may operate similarly to a floating-gate NAND memory cell 105 but, instead of or in addition to storing a charge on a charge trapping structure 120, a charge-trapping NAND memory cell 105 may store a charge representing a logic state in a dielectric material between the control gate 115 and a channel (e.g., a channel between a first node 130 and a second node 135). Thus, a charge-trapping NAND memory cell 105 may include a charge trapping structure 120, or may implement charge trapping functionality in one or more portions of dielectric material 125, among other configurations.

In some examples, each page of memory cells 105 may be connected to a corresponding word line 165, and each column of memory cells 105 may be connected to a corresponding bit line 155 (e.g., digit line). Thus, one memory cell 105 may be located at the intersection of a word line 165 and a bit line 155. This intersection may be referred to as an address of a memory cell 105. In some cases, word lines 165 and bit lines 155 may be substantially perpendicular to one another, and may be generically referred to as access lines or select lines.

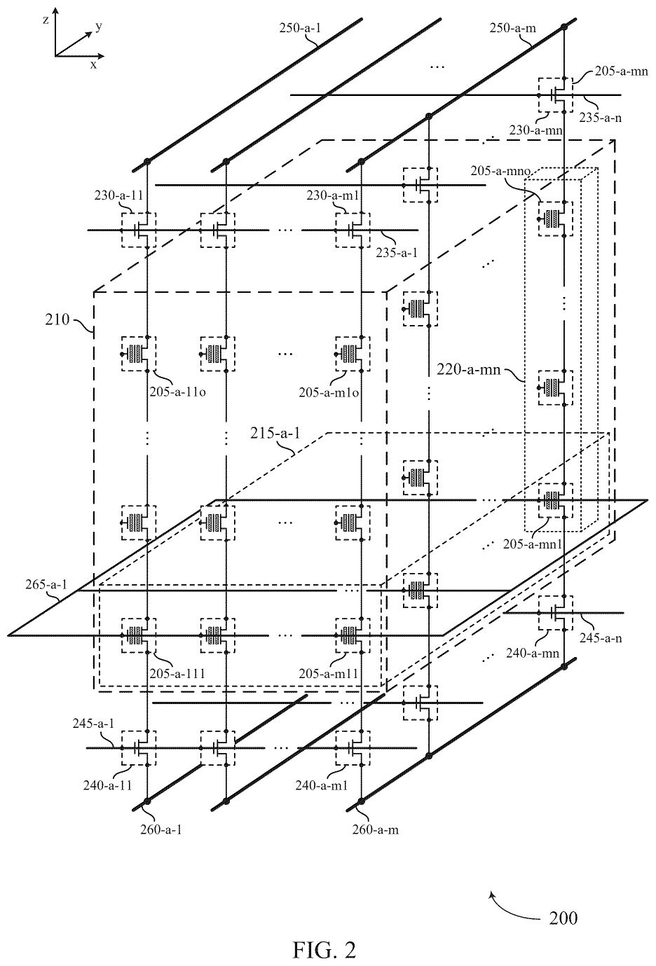

In some cases, a memory system 100 may include a three-dimensional (3D) memory array, where multiple two-dimensional (2D) memory arrays may be formed on top of one another. In some examples, such an arrangement may increase the quantity of memory cells 105 that may be fabricated on a single die or substrate as compared with 1D arrays, which, in turn, may reduce production costs, or increase the performance of the memory array, or both. In the example of FIG. 1, memory system 100 includes multiple levels (e.g., decks, layers, planes, tiers) of memory cells 105. The levels may, in some examples, be separated by an electrically insulating material. Each level may be aligned or positioned so that memory cells 105 may be aligned (e.g., exactly aligned, overlapping, or approximately aligned) with one another across each level, forming a memory cell stack 175. In some cases, memory cells aligned along a memory cell stack 175 may be referred to as a string of memory cells 105 (e.g., as described with reference to FIG. 2).

Accessing memory cells 105 may be controlled through a row decoder 160 and a column decoder 150. For example, the row decoder 160 may receive a row address from the memory controller 180 and activate an appropriate word line 165 based on the received row address. Similarly, the column decoder 150 may receive a column address from the memory controller 180 and activate an appropriate bit line 155. Thus, by activating one word line 165 and one bit line 155, one memory cell 105 may be accessed. As part of such accessing, a memory cell 105 may be read (e.g., sensed) by sense component 170. For example, the sense component 170 may be configured to determine the stored logic value of a memory cell 105 based on a signal generated by accessing the memory cell 105. The signal may include a current, a voltage, or both a current and a voltage on the bit line 155 for the memory cell 105 and may depend on the logic value stored by the memory cell 105. The sense component 170 may include various circuitry (e.g., transistors, amplifiers) configured to detect and amplify a signal (e.g., a current or voltage) on a bit line 155. The logic value of memory cell 105 as detected by the sense component 170 may be output via input/output component 190. In some cases, a sense component 170 may be a part of a column decoder 150 or a row decoder 160, or a sense component 170 may otherwise be connected to or in electronic communication with a column decoder 150 or a row decoder 160.

A memory cell 105 may be programmed or written by activating the relevant word line 165 and bit line 155 to enable a logic value (e.g., representing one or more bits of information) to be stored in the memory cell 105. A column decoder 150 or a row decoder 160 may accept data (e.g., from the input/output component 190) to be written to the memory cells 105. In the case of NAND memory, a memory cell 105 may be written by storing electrons in a charge trapping structure or an insulating layer.

A memory controller 180 may control the operation (e.g., read, write, re-write, refresh) of memory cells 105 through the various components (e.g., row decoder 160, column decoder 150, sense component 170). In some cases, one or more of a row decoder 160, a column decoder 150, and a sense component 170 may be co-located with a memory controller 180. A memory controller 180 may generate row and column address signals in order to activate a desired word line 165 and bit line 155. In some examples, a memory controller 180 may generate and control various voltages or currents used during the operation of memory system 100.

In accordance with examples as described herein, the memory system 100 may implement an improved memory architecture, where levels of the memory architecture are configured to have different voltage thresholds which may support improved accessibility of the sub-blocks. For example, the improved memory architecture may implement a stack of materials including levels with different voltage thresholds, such that the bit lines 155 associated with the levels may be associated with different voltage thresholds. Implementing different voltage thresholds for the bit lines 155 may improve accessibility for the corresponding sub-blocks, which may support individually accessing the sub-blocks using a logical pattern based on the different voltage thresholds. In some cases, the different voltage thresholds of the levels may be based on forming the stack of materials using improved processes. For example, to create different voltage thresholds of the levels, some levels may be subjected to a doping operation. In other examples, some levels may be replaced with different materials or a different quantity of the respective material. Implementing the improved memory architecture may improve reliability for performing access operations on the sub-blocks, which may increase overall performance of the memory system 100.

FIG. 2 shows an example of a memory architecture 200 that supports logical selector gate programming in accordance with examples as disclosed herein. The memory architecture 200 may be an example of a portion of a memory system, such as a memory system 100. Although some elements of a set of elements (e.g., an array of elements) are included in FIG. 2, some elements may be omitted for the sake of visibility and clarity of the depicted elements. Moreover, although some elements included in FIG. 2 are labeled with reference numbers, some other corresponding elements are not labeled, though they would be understood by a person having ordinary skill in the art to be the same as or similar to the labeled elements. Aspects of the memory architecture 200 may be described with reference to an x-direction, a y-direction, and a z-direction of the illustrated coordinate system.

The memory architecture 200 includes a three-dimensional array of memory cells 205, which may be examples of memory cells 105 described with reference to FIG. 1 (e.g., transistors 110, NAND memory cells). In some examples, the memory cells 205 may be connected in a 3D NAND configuration. For example, the memory cells 205 may be included in a block 210, which may be arranged as a 3D array of m memory cells along the x-direction, n memory cells along the y-direction, and o memory cells along the z-direction. Each memory cell 205 may be located (e.g., addressed) in accordance with an index i along the x-direction, an index j along the y-direction, and an index k along the z-direction (e.g., for locating a memory cell 205-a-ijk). A memory system 100 may include any quantity of one or more blocks 210 in accordance with examples as disclosed herein, and different blocks 210 may be adjacent along the x-direction, along the y-direction, or along the z-direction, or any combination thereof.

In the example of memory architecture 200, the block 210 may be divided into a set of pages 215 (e.g., a quantity of o pages 215) along the z-direction, including a page 215-a-1 associated with memory cells 205-a-111 through 205-a-mn1. In some examples, each page 215 may be associated with the same word line 265, (e.g., a word line 165 described with reference to FIG. 1), which may be coupled with a control gate 115 of each of the memory cells 205 of the page 215. For example, page 215-a-1 may be associated with a word line 265-a-1, and other pages 215-a-i may be associated with a different respective word line 265-a-i (not shown). In some examples, a word line 265 in accordance with the memory architecture 200 may be implemented as planar conductor (e.g., in an xy-plane) that is coupled with each of the memory cells 205 of the page 215.

In the example of memory architecture 200, the block 210 also may be divided into a set of strings 220 (e.g., a quantity of (m×n) strings 220) in an xy-plane, including a string 220-a-mn associated with memory cells 205-a-mn1 through 205-a-mno. In some examples, each string 220 may include a set of memory cells 205 connected in series (e.g., along the z-direction, in which a drain of one memory cell 205 in the string 220 may be coupled with a source of another memory cell 205 in the string 220). In some examples, memory cells 205 of a string 220 may be implemented along a common channel, such as a pillar channel (e.g., a columnar channel, a pillar of doped semiconductor) along the z-direction. Each memory cell 205 in a string 220 may be associated with a different word line 265, such that a quantity of word lines 265 in the memory architecture 200 may be equal to the quantity of memory cells 205 in a string 220. Accordingly, a string 220 may include memory cells 205 from multiple pages 215, and a page 215 may include memory cells 205 from multiple strings 220.

In some examples, memory cells 205 may be programmed (e.g., set to a logic 0 value) and read from in accordance with a granularity, such as at the granularity of a page 215 or portion thereof, but may not be erasable (e.g., reset to a logic 1 value) in accordance with the granularity, such as the granularity of a page 215 or portion thereof. For example, NAND memory may instead be erasable in accordance with a different (e.g., higher) level of granularity, such as at the level of granularity the block 210. In some cases, a memory cell 205 may be erased before it may be re-programmed. Different memory devices may have different read, write, or erase characteristics.

In some examples, each string 220 of a block 210 may be coupled with a respective transistor 230 (e.g., a string select transistor, a drain select transistor) at one end of the string 220 (e.g., along the z-direction) and a respective transistor 240 (e.g., a source select transistor, a ground select transistor) at the other end of the string 220. In some examples, a drain of each transistor 230 may be coupled with a bit line 250 of a set of bit lines 250 associated with the block 210, where the bit lines 250 may be examples of bit lines 155 described with reference to FIG. 1. A gate of each transistor 230 may be coupled with a select line 235 (e.g., a string select line, a drain select line). Thus, a transistor 230 may be used to couple a string 220 with a bit line 250 based on applying a voltage to the select line 235, and thus to the gate of the transistor 230. Although illustrated as separate lines along the x-direction, in some examples, select lines 235 may be common to all the transistors 230 associated with the block 210 (e.g., a commonly biased string select node). For example, like the word lines 265 of the block 210, select lines 235 associated with the block 210 may, in some examples, be implemented as a planar conductor (e.g., in an xy-plane) that is coupled with each of the transistors 230 associated with the block 210.

In some examples, a source of each transistor 240 associated with the block 210 may be coupled with a source line 260 of a set of source lines 260 associated with the block 210. In some examples, the set of source lines 260 may be associated with a common source node (e.g., a ground node) corresponding to the block 210. A gate of each transistor 240 may be coupled with a select line 245 (e.g., a source select line, a ground select line). Thus, a transistor 240 may be used to couple a string 220 with a source line 260 based on applying a voltage to the select line 245, and thus to the gate of the transistor 240. Although illustrated as separate lines along the x-direction, in some examples, select lines 245 also may be common to all the transistors 240 associated with the block 210 (e.g., a commonly biased ground select node). For example, like the word lines 265 of the block 210, select lines 245 associated with the block 210 may, in some examples, be implemented as a planar conductor (e.g., in an xy-plane) that is coupled with each of the transistors 240 associated with the block 210.

To operate the memory architecture 200 (e.g., to perform a program operation, a read operation, or an erase operation on one or more memory cells 205 of the block 210), various voltages may be applied to one or more select lines 235 (e.g., to the gate of the transistors 230), to one or more bit lines 250 (e.g., to the drain of one or more transistors 230), to one or more word lines 265, to one or more select lines 245 (e.g., to the gate of the transistors 240), to one or more source lines 260 (e.g., to the source of the transistors 240), or to a bulk for the memory cells 205 (not shown) of the block 210. In some cases, each memory cell 205 of a block 210 may have a common bulk, the voltage of which may be controlled independently of bulks for other blocks 210.

In some cases, as part of a read operation for a memory cell 205, a positive voltage may be applied to the corresponding bit line 250 while the corresponding source line 260 may be grounded or otherwise biased at a voltage lower than the voltage applied to the bit line 250. In some examples, voltages may be concurrently applied to the select line 235 and the select line 245 that are above the threshold voltages of the transistor 230 and the transistor 240, respectively, for the memory cell 205, thereby activating the transistor 230 and transistor 240 such that a channel associated with the string 220 that includes the memory cell 205 (e.g., a pillar channel) may be electrically connected with (e.g., electrically connected between) the corresponding bit line 250 and source line 260. A channel may be an electrical path through the memory cells 205 in the string 220 (e.g., through the sources and drains of the transistors in the memory cells 205 of the string 220) that may conduct current under some operating conditions.

In some examples, multiple word lines 265 (e.g., in some cases all word lines 265) of the block 210—except a word line 265 associated with a page 215 of the memory cell 205 to be read—may concurrently be set to a voltage (e.g., VREAD) that is higher than the threshold voltage (VT) of the memory cells 205. VREAD may cause all memory cells 205 in the unselected pages 215 to be activated so that each unselected memory cell 205 in the string 220 may maintain high conductivity within the channel. In some examples, the word line 265 associated with the memory cell 205 to be read may be set to a voltage, VTarget. Where the memory cells 205 are operated as SLC memory cells, VTarget may be a voltage that is between (i) VT of a memory cell 205 in an erased state and (ii) VT of a memory cell 205 in a programmed state.

When the memory cell 205 to be read exhibits an erased VT (e.g., VTarget>VT of the memory cell 205), the memory cell 205 may turn “ON” in response to the application of VTarget to the word line 265 of the selected page 215, which may allow a current to flow in the channel of the string 220, and thus from the bit line 250 to the source line 260. When the memory cell 205 to be read exhibits a programmed VT (e.g., VTarget<VT of the selected memory cell), the memory cell 205 may remain “OFF” despite the application of VTarget to the word line 265 of the selected page 215, and thus may prevent a current from flowing in the channel of the string 220, and thus from the bit line 250 to the source line 260.

A signal on the bit line 250 for the memory cell 205 (e.g., an amount of current below or above a threshold) may be sensed (e.g., by a sense component 170 as described with reference to FIG. 1), and may indicate whether the memory cell 205 became conductive or remained non-conductive in response to the application of VTarget to the word line 265 of the selected page 215. The sensed signal thus may be indicative of whether the memory cell 205 was in an erased state (e.g., storing a logic 1) or a programmed state (e.g., storing a logic 0). Though aspects of the example read operation above have been explained in the context of an SLC memory cell 205 for clarity, such techniques may be extended or altered and applied in the context of a multiple-level memory cell 205 (e.g., through the use of multiple values of VTarget corresponding to the different amounts of charge that may be stored in one multiple-level memory cell 205).

In some cases, as part of a program operation for a memory cell 205, charge may be added to a portion of the memory cell 205 such that current flow through the memory cell 205, and thus the corresponding string 220, may be inhibited when the memory cell 205 is later read. For example, charge may be injected into a charge trapping structure 120 as shown in memory cell 105-a of FIG. 1. In some cases, respective voltages may be applied to the word line 265 of the page 215 and the bulk of the memory cell 205 to be programmed such that a control gate 115 of the memory cell 205 is at a higher voltage than the bulk of the memory cell 205 (e.g., a positive voltage may be applied to the word line). Concurrently, voltages may be applied to the select line 235 and the select line 245 that are above the threshold voltages of the transistor 230 and the transistor 240, respectively, thereby activating the transistor 230 and the transistor 240, and the bit line 250 for the memory cell 205 to be programmed may be set to a relatively high voltage. This may cause an electric field such that electrons are pulled from the source of the memory cell 205 towards the drain. The electric field may also cause some of these electrons to be pulled through dielectric material 125 and thereby injected into the charge trapping structure 120 of the memory cell 205, through a process which may in some cases be referred to as tunnel injection.

In some cases, a single program operation may program some or all memory cells 205 in a page 215, as the memory cells 205 of the page 215 may all share a common word line 265 and a common bulk. For a memory cell 205 of the page 215 for which it is not desired to write a logic 0 (e.g., not desired to program the memory cell 205), the corresponding bit line 250 may be set to a relatively low voltage (e.g., ground), which may inhibit the injection of electrons into a charge trapping structure 120. Though aspects of the example program operation above have been explained in the context of an SLC memory cell 205 for clarity, such techniques may be extended and applied to the context of a multiple-level memory cell 205 (e.g., through the use of multiple programming voltages applied to the word line 265, or multiple passes or pulses of a programming voltage applied to the word line 265, corresponding to the different amounts of charge that may be stored in one multiple-level memory cell 205).

In some cases, as part of an erase operation for a memory cell 205, charge may be removed from a portion of the memory cell 205 such that current flow through the memory cell 205, and thus the corresponding string 220, may be uninhibited (e.g., allowed, at least to a greater extent) when the memory cell 205 is later read. For example, charge may be removed from a charge trapping structure 120 as shown in memory cell 105-a of FIG. 1. In some cases, respective voltages may be applied to the word line 265 of the page 215 and the bulk of the memory cell 205 to be erased such that a control gate 115 of the memory cell 205 is at a lower voltage than the bulk of the memory cell 205 (e.g., a positive voltage may be applied to the bulk), which may cause an electric field that pulls electrons out of the charge trapping structure 120 and into the bulk of the memory cell 205. In some cases, a single program operation may erase all memory cells 205 in a block 210, as the memory cells 205 of the block 210 may all share a common bulk.

In accordance with examples as described herein, a memory system may implement the memory architecture 200, where levels of the memory architecture 200 are configured to have different voltage thresholds which may support improved accessibility of the sub-blocks. For example, the memory architecture 200 may implement a stack of materials including levels with different voltage thresholds, such that the bit lines 250 associated with the levels may be associated with different voltage thresholds. Implementing different voltage thresholds for the bit lines 250 may improve accessibility for the corresponding sub-blocks, which may support individually accessing the sub-blocks using a logical pattern based on the different voltage thresholds. In some cases, the different voltage thresholds of the levels may be based on forming the stack of materials using improved processes. For example, to create different voltage thresholds of the levels, some levels may be subjected to a doping operation. In other examples, some levels may be replaced with different materials or a different quantity of the respective material. Implementing the memory architecture 200 may improve reliability for performing access operations on the sub-blocks, which may increase overall performance of the corresponding memory system.

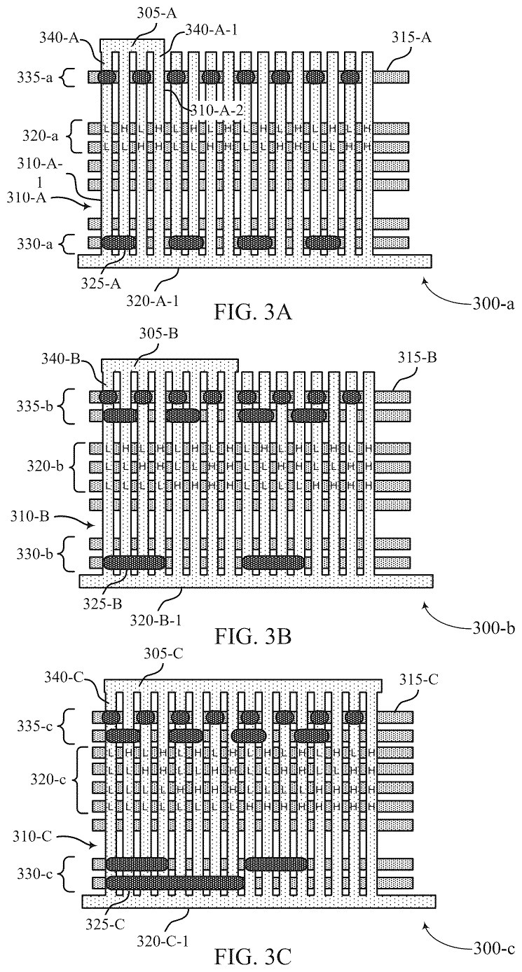

FIGS. 3A, 3B, and 3C show examples of logical architectures 300 (e.g., logical architecture 300-a, logical architecture 300-b, and logical architecture 300-c) that support logical selector gate programming in accordance with examples as disclosed herein. The logical architectures 300 may illustrate aspects or operations of a memory architecture, which may be an example of a memory architecture 200, as described with reference to FIG. 2. Likewise, the logical architectures 300 may be implemented by a memory system, which may be an example of a memory system 100, as described with reference to FIG. 1. The logical architectures 300 may illustrate a logical pattern for accessing a sub-block 310 of a memory architecture.

Each logical architecture 300 may include one or more blocks 305 (e.g., a block 305-a, a block 305-b, a block 305-c) operable for accessing a set of memory cells of the memory architecture. Each block 305 may include a quantity of sub-blocks 310 (e.g., a sub-block 310-a, a sub-block 310-b, a sub-block 310-c) each associated with a subset of the set of memory cells corresponding to the block 305. In some cases, the quantity of sub-blocks 310 within a block 305 may vary. For example, the logical architecture 300-a illustrates the block 305-a including a quantity of 4 sub-blocks 310-a, the logical architecture 300-b illustrates the block 305-b including a quantity of 8 sub-blocks 310-b, and the logical architecture 300-c illustrates the block 305-c including a quantity of 16 sub-blocks 310-b. Though the logical architectures 300 illustrate the blocks 305 including 4, 8, or 16 sub-blocks 310, the blocks 305 may implement a different quantity of sub-blocks 310 (e.g., 32 sub-blocks 310, 64 sub-blocks 310, among other examples).

Each sub-block 310 may be associated with a logical representation of a bit line 340 (e.g., a bit line 155, a bit line 250) of the memory architecture. While only a single bit line 340 (e.g., bit line 340-a, 340-b, 340-c, is identified for each logical architecture 300-a, 300-b, 300-c, multiple bit lines are depicted in each logical architecture 300-a, 300-b, 300-c. The memory architecture may include a quantity of bit lines, where each bit line corresponds to a respective sub-block 310 of the logical architecture 300. For example, accessing a sub-block 310 may include accessing the corresponding bit line 340-a, which may include applying a voltage to the bit line 340-a. In some cases, accessing a sub-block 310 may include applying a voltage to another access line 315 operable to couple with the corresponding bit line of the sub-block 310. For example, each logical architecture 300 includes a quantity of access lines 315 (e.g., access lines 315-a, access lines 315-b, access lines 315-c), which may be examples of word lines operable to couple with the bit lines corresponding to the sub-blocks 310.

In some cases, accessing one or more memory cells associated with a sub-block 310 may include applying an access voltage to an access line 315 and an access voltage to a bit line 340 corresponding to the sub-block 310. In some such cases, providing the access voltage to the bit line may include applying a voltage to one or more selection lines 320 (e.g., selection line 320-a, selection line 320-b, selection line 320-c) coupled with each bit line 340 of the block 305. That is, a sub-block 310 may be accessed based on applying voltages to the selection lines 320 to select the bit line corresponding to the sub-block 310.

In some such examples, each sub-block 310 of each block 305 may be independently addressable (e.g., independently accessible) based on each bit line being independently selectable. For example, a magnitude of the voltages applied to the selection lines 320 may be based on a logical addressing scheme associated with the sub-blocks 310 of each block 305. That is, a different magnitude may be applied to the selection lines 320 for accessing each bit line coupled with the selection lines 320. In some cases, the different magnitude may be based on a voltage threshold associated with accessing each bit line coupled with the selection lines 320. A representation of the logic that may be applied to the selection lines 320-a to cause a particular bit line 340 to be accessed is shown. For example, if bit line 340-a is to be selected, then a low voltage is applied to both selection lines 320-a. In contrast, if bit line 340-a-1 is to be selected, then a high voltage is applied to both selection lines 320-a. The voltage applied to the selection lines 320 is related to the voltage threshold formed in selector gate source side 330-a and selector gate drain side 335-a. That is, because each bit line may be associated with a different voltage threshold, each sub-block 310 may be accessed based on applying a different voltage along the selection lines 320. In some cases, each sub-block 310 may be associated with a logical address of a logical addressing scheme, where each logical address corresponds to a different magnitude of the voltages applied to the selection lines 320. In some such cases, each logical address may be a code (e.g., a binary multi-bit code) that may be implemented by the memory system to apply a voltage to the selection lines 320 that causes accessing of the corresponding sub-block 310.

In some cases, the sub-blocks 310 may be associated with different voltage thresholds based on a material configuration of the bit lines and access lines 315. For example, a sub-block 310 may include a different voltage threshold based on the corresponding bit line 340 being associated with a different voltage threshold. In some such examples, the bit line may be associated with a different voltage threshold based on a coupling between the bit line and an access line 315 including a different material configuration. In some such cases, the sub-blocks 310 may include portions 325 (e.g., portions 325-a, portions 325-b, portions 325-c) that are associated with a different voltage threshold (e.g., a higher voltage threshold), and a quantity of the portions 325 implemented in a respective sub-block 310 may affect the voltage that may activate the sub-block 310. That is, a sub-block 310 with a higher quantity of the portions 325 may be associated with a relatively higher voltage threshold than a sub-block 310 with a lower quantity of the portions 325.

For example, the sub-block 310-a-1 may be associated with two portions 325, whereas the sub-block 310-a-2 may be associated with no portions 325. Thus, the sub-block 310-a-1 may be associated with a relatively higher voltage threshold than the sub-block 310-a-2. In some such examples, the sub-block 310-a-1 may be accessed with a relatively higher voltage than the sub-block 310-a-2 based on the sub-block 310-a-1 having the relatively higher voltage threshold. In some cases, the sub-blocks 310 may include the portions 325 at a selector gate source side 330 (e.g., a selector gate source side 330-a, a selector gate source side 330-b, a selector gate source side 330-c) and/or at a selector gate drain side 335 (e.g., a selector gate drain side 335-a, a selector gate drain side 335-b, a selector gate drain side 335-c). In some such cases, the sub-blocks 310 may be addressable based on whether the portions 325 are located at the selector gate source side 330, the selector gate drain side 335, or any combination thereof.

In some cases, each sub-block 310 may be independently addressable based on each sub-block 310 of a block 305 being associated with a different configuration of the portions 325. For example, the logical architectures 300 may each include a quantity of sub-blocks 310 for the block 305, where each sub-block 310 may be associated with a different configuration of the portions 325. Thus, regardless of the quantity of sub-blocks 310 implemented at the block 310, each sub-block 310 may be independently addressable. Implementing independently addressable sub-blocks 310 within the logical architectures 300 may support independently accessible bit lines of a memory architecture, which may allow for greater memory cell density within the memory architecture. That is, the logical addressing schemes of the logical architectures 300 may support increased complexity for a corresponding memory architecture based on preventing voltage interactions between bit lines from causing incorrect addressing of the corresponding sub-blocks 310, among other advantages.

The logical architecture 300-c shows two access lines 315 with portions 325 at the selector gate source side 330-c and two access lines 315 with portions 325 at the selector gate drain side 335-c. In some examples, there may be three access lines 315 with portions 325 at the selector gate source side 330-c and only one access line 315 with portions 325 at the selector gate drain side 335-c. In other examples, there may be only a single access line 315 with portions 325 at the selector gate source side 330-c and three access lines 315 with portions 325 at the selector gate drain side 335-c.

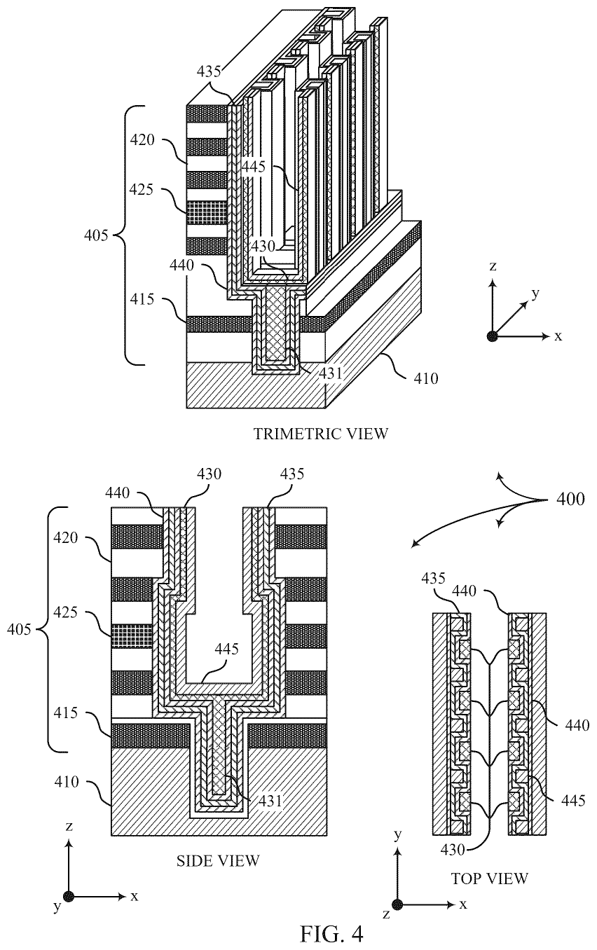

FIG. 4 shows an example of a memory architecture 400 that supports logical selector gate programming in accordance with examples as disclosed herein. The memory architecture 400 may implement aspects or operations of a memory architecture, which may be an example of a memory architecture 200 as described with reference to FIG. 2. Additionally, or alternatively, the memory architecture 400 may illustrate aspects of a logical architecture, which may be an example of logical architectures 300, as described with reference to FIGS. 3A through 3C. For example, the memory architecture 400 may illustrate structures and components operable to facilitate a logical addressing scheme of the logical architectures 300. FIG. 4 illustrates the memory architecture 400 from various cross-sectional views relative to the illustrated coordinate system. For example, FIG. 4 illustrates the memory architecture 400 from a trimetric view, a side view in an xz-plane, and a top view in an xy-plane.

The memory architecture 400 may include a stack of materials 405 deposited above (e.g., along the z-direction) a substrate 410 (e.g., a base material level upon which other materials may be deposited). The stack of materials 405 may include a quantity of levels, where each level may include a conductive material 415 or a dielectric material 420. For example, the stack of materials 405 may include levels of the conductive material 415 and levels of the dielectric material 420 deposited in an alternating pattern along the z-direction. In some cases, the conductive material 415 may be associated with forming access lines of the memory architecture 400. For example, the conductive material 415 may form word lines associated with accessing memory cells of the memory architecture 400.

The stack of materials 405 may include one or more levels 425 (e.g., portions 325, as described with reference to FIGS. 3A through 3C) with a different voltage threshold. In some cases, the one or more levels 425 may be positioned within the stack of materials 405 such that each level 425 may have an alternating level of the dielectric material 420 adjacent to the respective level 425 along the z-direction. In some such cases, the one or more levels 425 may replace the conductive material 415 within the one or more levels 425 of the stack of materials 405. In some examples, the conductive material 415 may be associated with a voltage threshold and the one or more levels 425 may be associated with a different voltage threshold based on a material configuration of the one or more levels 425. For example, the one or more levels 425 may include a relatively higher voltage threshold than the conductive material 415, such that a greater voltage may be applied to satisfy the voltage threshold of the one or more levels 425 than a voltage applied to satisfy the voltage threshold of the conductive material 415. In some implementations, the one or more levels 425 may include a dielectric material (e.g., a same material as the dielectric material 420, a different material from the dielectric material 420). In some implementations, the one or more levels 425 may include a conductive material different from the conductive material 415, or a different quantity of the conductive material 415. For example, the one or more levels 425 may include the conductive material 415 with a greater thickness along the z-direction than other levels of the conductive material 415. In some implementations, the one or more levels 425 may include a doping configuration, such as a p-type doping or an n-type doping of a base material, where the base material is a conductive material (e.g., the conductive material 415) or a dielectric material (e.g., the dielectric material 420).

The memory architecture 400 may include bit lines 430 extending through the stack of materials 405 along the z-direction. For example, the bit lines 430 may be U-shaped structures including conductive material (e.g., a same material as the conductive material 415, a different material from the conductive material 415) extending in pillars through the stack of materials 405. The bit lines 430 may extend from a bit line contact 431 (e.g., a selection line 320, as described with reference to FIGS. 3A through 3C) which extends through the stack of materials 405 and the substrate 410 along the y-direction. The bit line contact 431 may be a prismatic structure including the conductive material. In some cases, the bit lines 430 may be formed within the memory architecture such that adjacent bit lines along the y-direction are separated, which may form isolation regions between the bit lines 430.

The memory architecture 400 may include memory material 435 configured to function as memory cells when activated by a bit line 430 and a corresponding word line (e.g., associated with a respective level of the conductive material 415). In some cases, memory architecture 400 may include additional layers and supporting structures associated with the memory material 435 and the bit lines 430. For example, the memory architecture 400 may include a barrier material 440 surrounding the memory material 435 relative to the x-direction. Likewise, the memory architecture 400 may include a barrier material 445 surrounding the bit lines 430 and filling the isolation regions between the bit lines 430. In some such examples, the barrier material 440 and the barrier material 445 may support electrical functions of the bit lines 430 and the memory material 435.

The bit lines 430 of the memory architecture 400 may be associated with various sub-blocks 310 of the logical architectures 300, as described with reference to FIGS. 3A through 3C. In some cases, each sub-block 310 may be independently addressable based on each bit line 430 being associated with a different configuration of the one or more levels 425. For example, the memory architecture 400 may each include a quantity of bit lines 430 each associated with a different configuration of the one or more levels 425, which may cause each bit line 430 to be associated with a different voltage threshold. In some such examples, each bit line 430 may be accessible via a different voltage applied to selection lines (not shown in FIG. 4), thus each sub-block 310 may be independently addressable due to an associated logical addressing scheme based on the one or more levels 425 (in combination with the different voltages applied to the selection lines). Implementing independently accessible bit lines 430 within the memory architecture 400 may support independently addressable sub-blocks 310 of a logical architecture 300, which may allow for greater memory cell density within the memory architecture 400. That is, the logical addressing schemes of the logical architectures 300 may support increased complexity for the memory architecture 400 based on preventing voltage interactions between bit lines 430 from causing incorrect addressing of the corresponding sub-blocks 310, among other advantages.

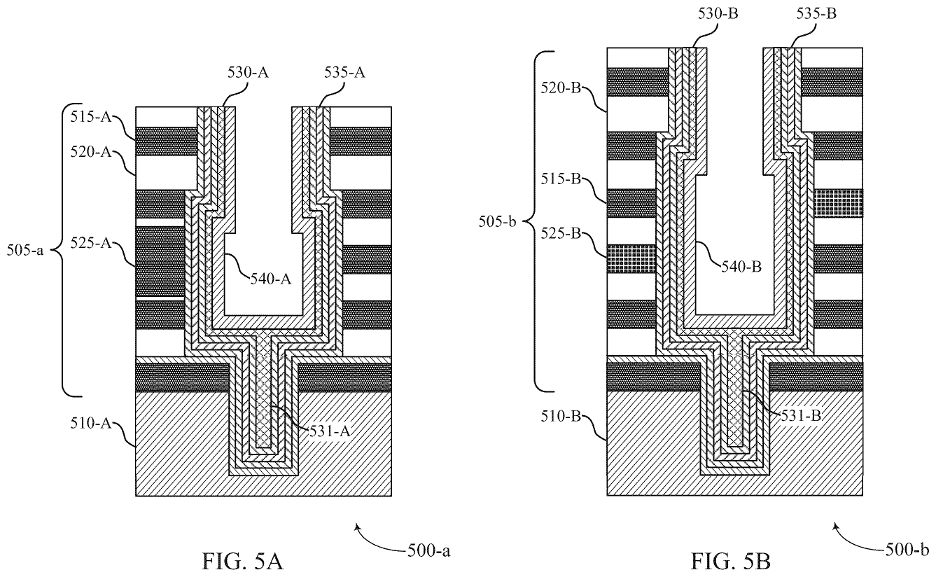

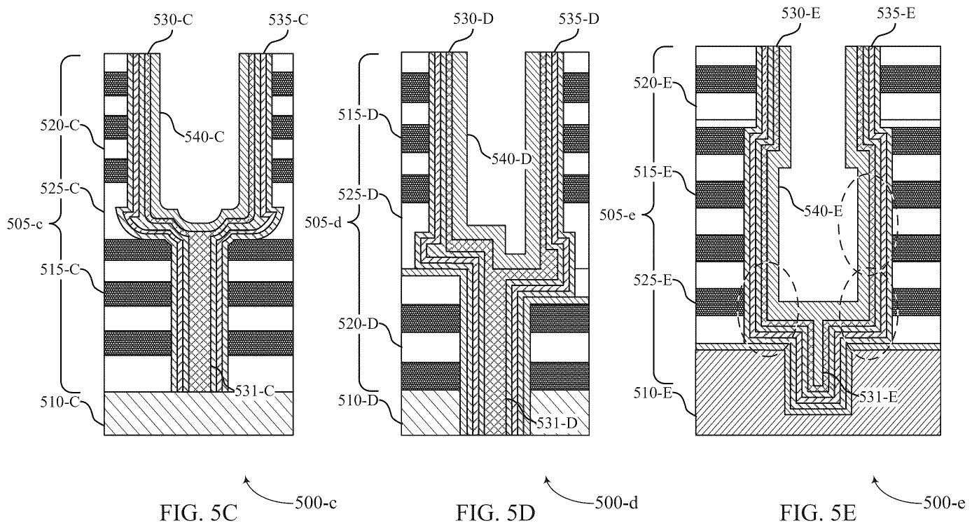

FIGS. 5A, 5B, 5C, 5D, and 5E show examples of memory architectures 500 (e.g., memory architecture 500-a, memory architecture 500-b, memory architecture 500-c, memory architecture 500-d, memory architecture 500-e) that support logical selector gate programming in accordance with examples as disclosed herein. The memory architectures 500 may implement aspects or operations of a memory architecture, which may be an example of a memory architecture 400 as described with reference to FIG. 4. Additionally, or alternatively, the memory architectures 500 may illustrate aspects of a logical architecture, which may be an example of logical architectures 300, as described with reference to FIGS. 3A through 3C. FIGS. 5A through 5E each illustrate a different material configuration of the memory architecture 400 that may be operable to facilitate a logical addressing scheme of the logical architectures 300.

Each memory architecture 500 may include a stack of materials 505 (e.g., a stack of materials 405) deposited above a substrate 510 (e.g., a substrate 410). The stack of materials 505 may include a quantity of levels, such as alternating levels of a conductive material 515 (e.g., a conductive material 415) and a dielectric material 520 (e.g., a dielectric material 420). In some cases, the conductive material 515 may be associated with forming access lines (e.g., word lines) of the respective memory architecture 500. Each memory architecture 500 may include bit lines 530 (e.g., bit lines 430) extending through the stack of materials 505. The bit lines 530 may extend from a bit line contact 531 (e.g., a bit line contact 431) which extends through the stack of materials 505 (e.g., and the substrate 510). Each memory architecture 500 may include memory material 535 (e.g., memory material 435) configured to function as memory cells when activated by a bit line 530 and a corresponding access line (e.g., associated with a respective level of the conductive material 515). In some cases, each memory architecture 500 may include additional barrier materials 540 (e.g., barrier materials 440 and 445) and supporting structures associated with the memory material 535 and the bit lines 530.

Each memory architecture 500 may include one or more levels 525 (e.g., levels 425) within the stack of materials 505 configured to have a different voltage threshold. The memory architectures 500 of the FIGS. 5A through 5E may each implement a different material configuration for the one or more levels 525. For example, FIG. 5A illustrates the level 525-a implemented at one of the levels of the conductive material 515-a, where the level 525-a include a different quantity of the conductive material 515-a. That is, the levels of the conductive material 515-a within the stack of materials 505-a may be associated with a same thickness, however the level 525-a may be associated with a different thickness (e.g., a relatively greater thickness). Because the level 525-a is associated with a different thickness than the levels of the conductive material 515-a, the level 525-a may be associated with a different voltage threshold than the levels of the conductive material 515-a. In another example, FIG. 5B illustrates the levels 525-b implemented at the levels of the conductive material 515-b, where the levels 525-b include a different material than the conductive material 515-a. That is, the levels 525-b may include a dielectric material (e.g., silicon oxide), which is different from the conductive material 515-b. Because the levels 525-b are associated with a different material than the conductive material 515-b, the levels 525-b may be associated with a different voltage threshold than the levels of the conductive material 515-b.

In some cases, each memory architecture 500 may include the one or more levels 525 configured to have a different voltage threshold based on a material configuration of the bit lines 530. For example, FIG. 5C illustrates each bit line 530-c including a horizontal segment coupled with the bit line contact 531-c, a vertical segment extending through the stack of material 505-c, and a connection segment coupling the horizontal segment with the vertical segment. In some such examples, adjacent bit lines 530-c may include the connection segments at (e.g., coplanar with) levels of the stack of materials 505-c. To provide space to implement the connection segments at the respective levels of the stack of materials 505-c, the levels may be associated with a different thickness than other levels of the stack of materials 505-c. Because the levels are associated with different thicknesses, the levels may be associated with different voltage thresholds. In another example, FIG. 5D illustrates each bit line 530-d including a horizontal segment coupled with the bit line contact 531-d, and a vertical segment extending through the stack of material 505-d. However, adjacent bit lines 530-d may implement the respective horizontal segments at different heights, such that each of the adjacent bit lines 530-d may include the horizontal segment at (e.g., coplanar with) a different level of the stack of materials 505-d. That is, because the horizontal segments of the bit lines 530-d are associated with different levels, the levels may be associated with different voltage thresholds.

In some cases, each memory architecture 500 may include the one or more levels 525-e configured to have a different voltage threshold based on a doping configuration of the levels 525-e. For example, FIG. 5E illustrates each level 525-e being associated with a doping configuration, which may include a p-type doping or an n-type doping. That is, the levels of the conductive material 515-e or the levels of the dielectric material 520-e within the stack of materials 505-e may not be associated with a doping configuration, however the levels 525-e may be associated with a doping configuration, which may include a dopant applied to a base material, where the base material may be the conductive material 515-e or the dielectric material 520-e. Because the levels 525-e are associated with a different doping configuration than the levels of the conductive material 515-e or the dielectric material 520-e, the level 525-e may be associated with a different voltage threshold than the levels of the conductive material 515-e or the dielectric material 520-e.

Implementing the levels 525 with a different voltage threshold may support independently accessing the bit lines 530 within the memory architectures 500. Independently accessible bit lines 530 may support individually addressable sub-blocks 310 of a logical architecture 300, which may allow for greater memory cell density within the memory architectures 500. That is, the logical addressing schemes of the logical architectures 300 may support increased complexity for the corresponding memory architectures 500 based on preventing voltage interactions between bit lines 530 from causing incorrect addressing of the corresponding sub-blocks 310, among other advantages.

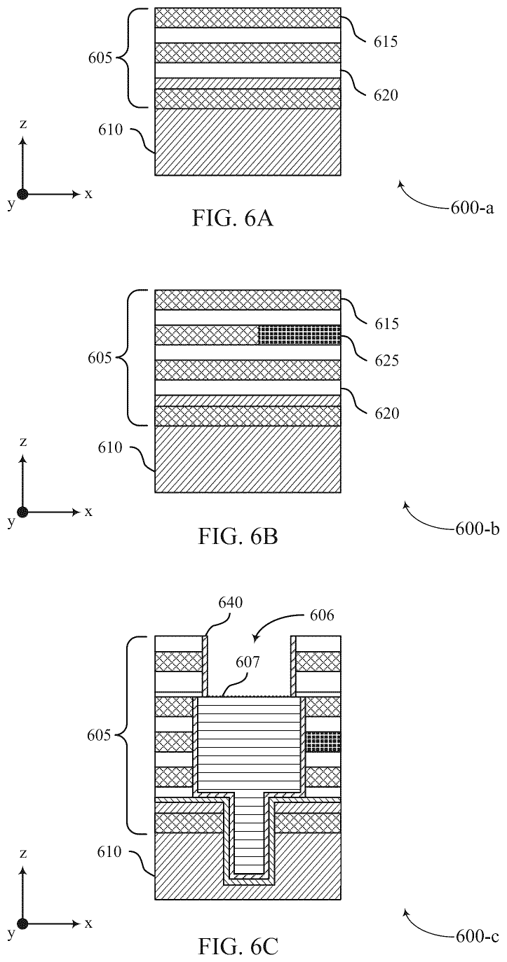

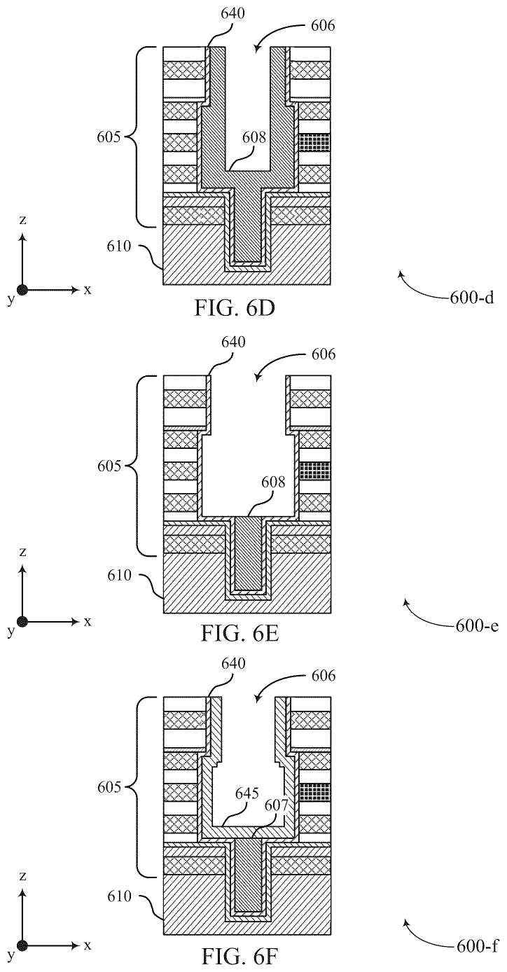

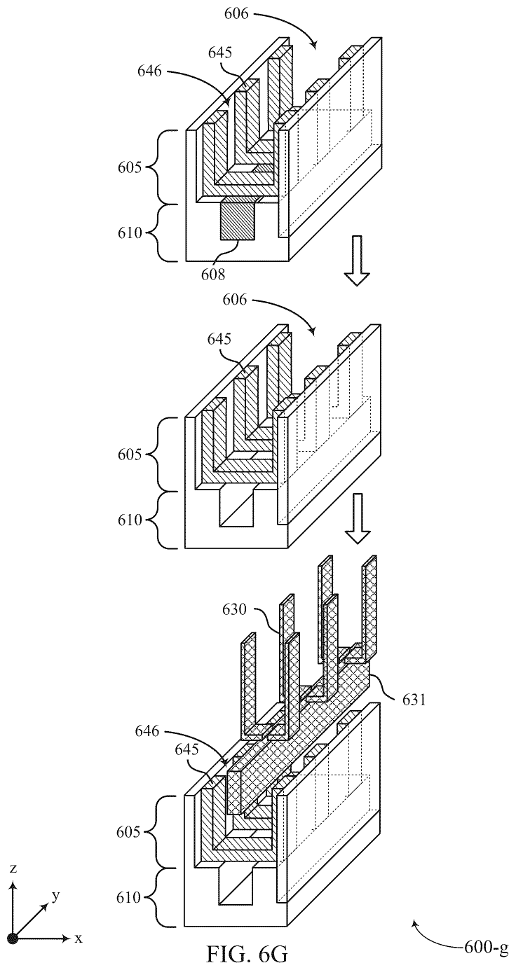

FIGS. 6A, 6B, 6C, 6D, 6E, 6F, and 6G show examples of processing steps 600 (e.g., processing step 600-a, processing step 600-b, processing step 600-c, processing step 600-d, processing step 600-e, processing step 600-f, processing step 600-g) that support logical selector gate programming in accordance with examples as disclosed herein. FIGS. 6A through 6G illustrate processing steps 600 associated with forming a memory architecture, which may be an example of memory architectures 500, as described with reference to FIGS. 5A through 5E. Additionally, or alternatively, the memory architecture may implement aspects or operations of a memory architecture 400 and may be configured to support logical architectures 300, as described with reference to FIGS. 3A through 4. The processing steps 600 may illustrate operations associated with forming independently accessible bit lines of the memory architecture, which may support independently addressable sub-blocks of the corresponding logical architecture.

For illustrative purposes, aspects of the memory architecture may be described with reference to an x-direction, a y-direction, and a z-direction of the illustrated coordinate systems. For example, the processing steps 600 illustrate the memory architecture from side views where a substrate 610 of the memory architecture may be associated with an xy-plane, where the memory architecture extends a distance along the z-direction. Although the processing steps 600 illustrate examples of relative dimensions and quantities of various features, aspects of the memory architecture may be implemented with other relative dimensions or quantities of such features in accordance with examples as disclosed herein. In the following description of the processing steps 600, some methods, techniques, processes, and operations may be performed in different orders or at different times. Further, some operations may be left out of the processing steps 600, or other operations may be added to the processing steps 600.

Operations illustrated in and described with reference to FIGS. 6A through 6G may be performed by a manufacturing system, such as a semiconductor fabrication system configured to perform additive operations such as deposition, bonding, and/or coupling, subtractive operations such as etching, trenching, planarizing, and/or polishing, and supporting operations such as masking, patterning, photolithography, and/or aligning, among other operations that support the described techniques. In some examples, operations performed by such a manufacturing system may be supported by one or more controllers, such as one or more processors or processing circuitry, or its components as described herein.

FIG. 6A illustrates the processing step 600-a associated with forming a stack of materials 605 (e.g., a stack of materials 505). The stack of materials 605 may include alternating levels of a conductive material 615 (e.g., a conductive material 515) and a dielectric material 620 (e.g., a dielectric material 520) deposited above a substrate 610. For example, a level of the conductive material 615 may be deposited above the substrate 610 (e.g., along the z-direction) and a level of dielectric material 620 may be deposited above the level of the conductive material 615 in an alternating pattern.

FIG. 6B illustrates the processing step 600-b associated with forming a level 625 within the stack of materials 605. The level 625 may be associated with a different voltage threshold than other levels of the stack of materials 605. For example, the level 625 may be implemented at a level of the stack of materials 605 otherwise associated with the conductive material 615, however the level 625 may have a different voltage threshold than the conductive material 615. In some cases, the level 625 may be implemented at least partially within an existing level of the stack of materials 605, such as at a portion of the existing level. In some cases, the level 625 may be associated with a different material configuration. For example, the level 625 may include a dielectric material instead of the conductive material 615. In another example, the level 625 may include the conductive material 615 implemented with a different thickness along the z-direction. In some examples, the level 625 may include a base material doped to form a doping configuration that is associated with a different voltage threshold. In some cases, forming the level 625 may include forming the level 625 while depositing the alternating levels of the stack of materials 605. In other cases, forming the level 625 may include forming the level 625 after depositing the alternating levels of the stack of materials 605. For example, the associated level may be masked, etched, and redeposited to form the level 625.

FIG. 6C illustrates the processing step 600-c associated with forming a plug 607 within the stack of materials 605 and the substrate 610. For example, a cavity 606 may be formed extending through the stack of materials 605 and at least partially through the substrate 610 along the z-direction. In some cases, the cavity 606 may be etched through the stack of materials 605 and the substrate 610 such that the cavity 606 may include a portion associated with the substrate and including a first width, and another portion associated with the stack of materials 605 and including a second width greater than the first width. After forming the cavity 606, a barrier material 640 may be formed along sidewalls of the cavity 606. The plug 607 may be deposited into the cavity 606 and may be adjacent to the barrier material 640. In some cases, the plug 607 may fill a portion of the cavity 606, such that the plug 607 may not extend to a level coplanar with a top level of the stack of materials 605.

FIG. 6D illustrates the processing step 600-d associated with forming a sacrificial film 608 within the cavity 606. For example, the processing step 600-d may include removing the plug 607 from the cavity 606. After removing the plug 607, the sacrificial film 608 may be formed within the cavity 606 and may be deposited along the sidewalls of the cavity 606. In some cases, the sacrificial film 608 may be deposited such that the sacrificial film 608 extends to a level coplanar with the top level of the stack of materials 605. In some examples, the sacrificial film 608 may be deposited such that the sacrificial film 608 includes the cavity 606 extending at least partially through the center of the sacrificial film 608.

FIG. 6E illustrates the processing step 600-e associated with removing a portion of the sacrificial film 608 from the cavity 606. For example, the sacrificial film 608 may be recessed such that the sacrificial film 608 may fill the cavity to a level coplanar with the portion of the cavity 606 associated with the substrate 610. That is, the sacrificial film 608 may form a plug within the portion of the cavity 606 associated with the substrate 610.

FIG. 6F illustrates the processing step 600-f associated with forming a barrier material 645 within the cavity 606. For example, the processing step 600-f may include depositing the barrier material 645 within the cavity 606 such that the barrier material 645 is adjacent to the barrier material 640. In some examples, the barrier material 645 may be deposited such that the barrier material 645 extends to a level coplanar with the top level of the stack of materials 605 and may include the cavity 606 extending at least partially through the center of the barrier material 645. In some implementations, the barrier material 645 may be deposited above the sacrificial film 608 forming the plug within the portion of the cavity 606 associated with the substrate 610.

FIG. 6G illustrates the processing step 600-g associated with forming bit lines 630. First, the processing step 600-g may include removing portions of the barrier material 645 within the cavity 606. For example, portions of the barrier material 645 may be removed to form isolation regions 646 between adjacent sections of the barrier material 645. The isolation regions 646 may be associated with a size of the cavity 606. In some cases, removing the portions of the barrier material 645 may include masking the adjacent sections of the barrier material 645 and removing unmasked portions of the barrier material 645. After removing portions of the barrier material 645 to form the isolation regions 646, the sacrificial film 608 may be removed from the memory architecture. For example, the sacrificial film 608 forming the plug within the portion of the cavity 606 associated with the substrate 610 may be removed such that the cavity 606 is extended again at least partially through the substrate 610. After removing the sacrificial film 608 from the memory architecture, a bit line contact 631 (e.g., a bit line contact 531) may be formed within the cavity 606. That is, the bit line contact 631 may be deposited within the cavity 606 created by removing the sacrificial film 608, such that the bit line contact 631 may form a plug within the portion of the cavity 606 associated with the substrate 610. Additionally, bit lines 630 may be formed within the cavity 606. The bit lines 630 may be formed based on depositing the bit lines 630 within the isolation regions 646 of the cavity 606. The bit lines 630 may form a U-shape and may connect with the bit line contact 631. After forming the bit lines 630, a memory material may be formed adjacent to the bit lines 630 and the barrier material 645.

Implementing the processing steps 600 may support forming the levels 625 with a different voltage threshold. The levels 625 may support independently accessing the bit lines 630, which may support individually addressable sub-blocks 310 of a logical architecture 300. That is, the processing steps 600 may form a memory architecture which have a greater memory cell density, and the corresponding logical architecture may support increased complexity.

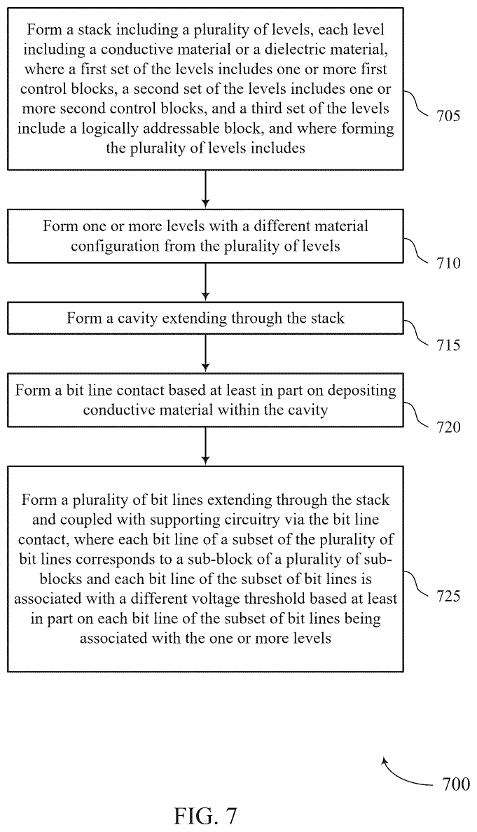

FIG. 7 shows a flowchart illustrating a method or methods 700 that support logical selector gate programming in accordance with examples as disclosed herein. The operations of method 700 may be implemented by a manufacturing system or one or more controllers associated with a manufacturing system. In some examples, one or more controllers may execute a set of instructions to control one or more functional elements of the manufacturing system to perform the described functions. Additionally, or alternatively, one or more controllers may perform aspects of the described functions using special-purpose hardware.

At 705, the method may include forming a stack including a plurality of levels, each level including a conductive material or a dielectric material, where a first set of the levels includes one or more first control blocks, a second set of the levels includes one or more second control blocks, and a third set of the levels include a logically addressable block, and where forming the plurality of levels includes.

At 710, the method may include forming one or more levels with a different material configuration from the plurality of levels.

At 715, the method may include forming a cavity extending through the stack.

At 720, the method may include forming a bit line contact based at least in part on depositing conductive material within the cavity.

At 725, the method may include forming a plurality of bit lines extending through the stack and coupled with supporting circuitry via the bit line contact, where each bit line of a subset of the plurality of bit lines corresponds to a sub-block of a plurality of sub-blocks and each bit line of the subset of bit lines is associated with a different voltage threshold based at least in part on each bit line of the subset of bit lines being associated with the one or more levels.

In some examples, an apparatus (e.g., a manufacturing system) as described herein may perform a method or methods, such as the method 700. The apparatus may include features, circuitry, logic, means, or instructions (e.g., a non-transitory computer-readable medium storing instructions executable by one or more controllers to control one or more functional elements of the manufacturing system), or any combination thereof for performing the following aspects of the present disclosure:

Aspect 1: A method or apparatus including operations, features, circuitry, logic, means, or instructions, or any combination thereof for forming a stack including a plurality of levels, each level including a conductive material or a dielectric material, where a first set of the levels includes one or more first control blocks, a second set of the levels includes one or more second control blocks, and a third set of the levels include a logically addressable block, and where forming the plurality of levels includes; forming one or more levels with a different material configuration from the plurality of levels; forming a cavity extending through the stack; forming a bit line contact based at least in part on depositing conductive material within the cavity; and forming a plurality of bit lines extending through the stack and coupled with supporting circuitry via the bit line contact, where each bit line of a subset of the plurality of bit lines corresponds to a sub-block of a plurality of sub-blocks and each bit line of the subset of bit lines is associated with a different voltage threshold based at least in part on each bit line of the subset of bit lines being associated with the one or more levels.

Aspect 2: The method or apparatus of aspect 1, where forming the plurality of levels includes operations, features, circuitry, logic, means, or instructions, or any combination thereof for depositing the dielectric material in an alternating pattern with the conductive material to form the plurality of levels, where forming the one or more levels includes and depositing a dielectric material at the one or more levels.

Aspect 3: The method or apparatus of any of aspects 1 through 2, where forming the plurality of levels includes operations, features, circuitry, logic, means, or instructions, or any combination thereof for depositing the dielectric material in an alternating pattern with the conductive material of a first thickness to form the plurality of levels, where forming the one or more levels includes and depositing a conductive material of a second thickness at the one or more levels.

Aspect 4: The method or apparatus of any of aspects 1 through 3, where forming the plurality of levels includes operations, features, circuitry, logic, means, or instructions, or any combination thereof for depositing the dielectric material in an alternating pattern with the conductive material to form the plurality of levels, where forming the one or more levels includes and doping a material at the one or more levels with a dopant.

Aspect 5: The method or apparatus of any of aspects 1 through 4, further including operations, features, circuitry, logic, means, or instructions, or any combination thereof for forming a plurality of memory cells at the plurality of levels in the stack, where at least a portion of the plurality of memory cells are organized into a block that is divided into the plurality of sub-blocks, each sub-block being independently accessible from other sub-blocks of the plurality of sub-blocks.

Aspect 6: The method or apparatus of any of aspects 1 through 5, further including operations, features, circuitry, logic, means, or instructions, or any combination thereof for forming layers of materials within the cavity, the layers of materials including a first protective liner, a storage material, and a second protective liner and where forming the bit line contact and the plurality of bit lines is based at least in part on forming the layers of materials within the cavity.

Aspect 7: The method or apparatus of any of aspects 1 through 6, where forming the plurality of bit lines includes operations, features, circuitry, logic, means, or instructions, or any combination thereof for depositing the conductive material along a bottom wall of the cavity and along sidewalls of the cavity and etching, back at least in part on a mask, alternating regions of the conductive material to form a plurality of U-shaped strips of the conductive material that extend along the bottom wall of the cavity and the sidewalls of the cavity, where each U-shaped strip is physically isolated from other U-shaped strips of the plurality of U-shaped strips.

It should be noted that the described methods include possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 8: A memory device, including: a stack of materials that form memory cells at multiple levels in the stack of materials, where at least a portion of the memory cells are organized into a block that is divided into a plurality of sub-blocks, each sub-block being independently accessible from other sub-blocks of the plurality of sub-blocks; a plurality of bit lines extending through the stack of materials that correspond to the block; and a bit line contact coupling a subset of bit lines of the plurality of bit lines with supporting circuitry, where each bit line of the subset of bit lines corresponds to one of the sub-blocks of the plurality of sub-blocks; and where the stack of materials includes one or more levels configured to provide different voltage thresholds for each bit line of the subset of bit lines, and where a bit line of the subset of bit lines is selectable based at least in part on the different voltage thresholds.

Aspect 9: The memory device of aspect 8, where the stack of materials includes first dielectric materials and conductive materials, the one or more levels are formed at a subset of the conductive materials in the stack of materials.

Aspect 10: The memory device of aspect 9, where a first voltage threshold of a first bit line of the subset of bit lines is based at least in part on materials formed in the one or more levels, and a second voltage threshold of a second bit line of the subset of bit lines is different than the first voltage threshold based at least in part on materials formed in the one or more levels.

Aspect 11: The memory device of aspect 10, where a second dielectric material is located at a subset of the one or more levels associated with the first bit line, the first voltage threshold of the first bit line is based at least in part on the second dielectric material at the subset of the one or more levels, and each bit line of the subset of bit lines is associated with a different voltage threshold based on each bit line being associated with different configurations of the second dielectric material at the one or more levels.

Aspect 12: The memory device of any of aspects 8 through 11, where the stack of materials includes dielectric materials and conductive materials, the conductive materials have a first thickness, the one or more levels are formed where a subset of the conductive materials have a second thickness different than the first thickness.

Aspect 13: The memory device of aspect 12, where a first voltage threshold of a first bit line of the subset of bit lines is associated with the first thickness and a second voltage threshold of a second bit line of the subset of bit lines is associated with the second thickness.

Aspect 14: The memory device of any of aspects 8 through 13, where the stack of materials includes dielectric materials and conductive materials, the one or more levels are associated with doping with at least one dopant at a same layer as a subset of the conductive materials.

Aspect 15: The memory device of aspect 14, where the stack of materials includes a plurality of doped regions, and each doped region of the plurality of doped regions includes a gradient of concentration of the at least one dopant.

Aspect 16: The memory device of any of aspects 14 through 15, where a first voltage threshold of a first bit line of the subset of bit lines is based at least in part on a first doping region doped with at least one dopant, and a second voltage threshold of a second bit line of the subset of bit lines is based at least in part on a second doping region.

Aspect 17: The memory device of aspect 16, where each level of the one or more levels includes a quantity of at least one dopant.

Aspect 18: The memory device of any of aspects 8 through 17, further including: a first sub-block of the plurality of sub-blocks associated with a first voltage threshold based at least in part on the first sub-block corresponding to a first bit line associated with the first voltage threshold; and a second sub-block of the plurality of sub-blocks associated with a second voltage threshold based at least in part on the second sub-block corresponding to a second bit line associated with the second voltage threshold.

Aspect 19: The memory device of aspect 18, where selecting the first sub-block includes applying a first voltage to the subset of bit lines corresponding to the plurality of sub-blocks based at least in part on the first voltage being associated with satisfying the first voltage threshold, and. where selecting the second sub-block includes applying a second voltage to the subset of bit lines corresponding to the plurality of sub-blocks based at least in part on the second voltage being associated with satisfying the second voltage threshold.

Aspect 20: The memory device of aspect 19, where the memory device is configured to refrain from selecting the sub-block based at least in part on applying the first voltage to the plurality of sub-blocks.

Aspect 21: The memory device of any of aspects 8 through 20, where: the stack of materials extends above a substrate in a first direction; the bit line contact extends in a second direction perpendicular to the first direction; and the plurality of bit lines extend at least partially through the stack of materials in the first direction, and each bit line of the subset of bit lines is coupled with the bit line contact within a respective contact region and is physically isolated from other bit lines of the subset of bit lines within other regions different from the respective contact region.

Aspect 22: The memory device of aspect 21, where each bit line includes: a first segment extending along a third direction within the stack of materials, the third direction perpendicular to the second direction; and a second segment extending along the first direction within the stack of materials.

Aspect 23: The memory device of aspect 22, where a first bit line of the plurality of bit lines includes the first segment at a first height above the substrate in the first direction, and a second bit line of the plurality of bit lines adjacent to the first bit line in the third direction includes the first segment at a second height above the substrate in the first direction, the first height is different than the second height.

Aspect 24: The memory device of any of aspects 8 through 23, further including: a plurality of word lines each associated with a respective level of the stack of materials, where accessing a memory cell is based at least in part on accessing a word line of the plurality of word lines that is associated with a respective bit line of the plurality of bit lines.

Aspect 25: The memory device of any of aspects 8 through 24, further including: a plurality of separation regions between the plurality of bit lines within the stack of materials, where each pair of adjacent bit lines is physically isolated from each other by a respective separation region of the plurality of separation regions.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The term “layer” or “level” used herein refers to a stratum or sheet of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials, or combinations thereof. In some examples, one layer or level may be composed of two or more sublayers or sublevels.

As used herein, the term “electrode” may refer to an electrical conductor, and in some examples, may be employed as an electrical contact to a memory cell or other component of a memory array. An electrode may include a trace, wire, conductive line, conductive layer, or the like that provides a conductive path between elements or components of a memory array.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed and second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory device, comprising:
a stack of materials that form memory cells at multiple levels in the stack of materials, wherein at least a portion of the memory cells are organized into a block that is divided into a plurality of sub-blocks, each sub-block being independently accessible from other sub-blocks of the plurality of sub-blocks;
a plurality of bit lines extending through the stack of materials that correspond to the block; and
a bit line contact coupling a subset of bit lines of the plurality of bit lines with supporting circuitry, wherein each bit line of the subset of bit lines corresponds to one of the sub-blocks of the plurality of sub-blocks;
wherein the stack of materials comprises one or more levels configured to provide different voltage thresholds for each bit line of the subset of bit lines, and wherein a bit line of the subset of bit lines is selectable based at least in part on the different voltage thresholds.

2. The memory device of claim 1, wherein:
the stack of materials comprises first dielectric materials and conductive materials, and
the one or more levels are formed at a subset of the conductive materials in the stack of materials.

3. The memory device of claim 2, wherein:
a first voltage threshold of a first bit line of the subset of bit lines is based at least in part on materials formed in the one or more levels, and
a second voltage threshold of a second bit line of the subset of bit lines is different than the first voltage threshold based at least in part on materials formed in the one or more levels.

4. The memory device of claim 3, wherein:
a second dielectric material is located at a subset of the one or more levels associated with the first bit line,
the first voltage threshold of the first bit line is based at least in part on the second dielectric material at the subset of the one or more levels, and
and each bit line of the subset of bit lines is associated with a different voltage threshold based on each bit line being associated with different configurations of the second dielectric material at the one or more levels.

5. The memory device of claim 1, wherein:
the stack of materials comprises dielectric materials and conductive materials,
the conductive materials have a first thickness, and
the one or more levels are formed where a subset of the conductive materials have a second thickness different than the first thickness.

6. The memory device of claim 5, wherein a first voltage threshold of a first bit line of the subset of bit lines is associated with the first thickness and a second voltage threshold of a second bit line of the subset of bit lines is associated with the second thickness.

7. The memory device of claim 1, wherein:
the stack of materials comprises dielectric materials and conductive materials, and
the one or more levels are associated with doping with at least one dopant at a same layer as a subset of the conductive materials.

8. The memory device of claim 7, wherein:
the stack of materials comprises a plurality of doped regions, and
each doped region of the plurality of doped regions comprises a gradient of concentration of the at least one dopant.

9. The memory device of claim 7, wherein:
a first voltage threshold of a first bit line of the subset of bit lines is based at least in part on a first doping region doped with at least one dopant, and
a second voltage threshold of a second bit line of the subset of bit lines is based at least in part on a second doping region.

10. The memory device of claim 9, wherein each level of the one or more levels comprises a quantity of at least one dopant.

11. The memory device of claim 1, further comprising:
a first sub-block of the plurality of sub-blocks associated with a first voltage threshold based at least in part on the first sub-block corresponding to a first bit line associated with the first voltage threshold; and
a second sub-block of the plurality of sub-blocks associated with a second voltage threshold based at least in part on the second sub-block corresponding to a second bit line associated with the second voltage threshold.

12. The memory device of claim 11, wherein:
selecting the first sub-block comprises applying a first voltage to the subset of bit lines corresponding to the plurality of sub-blocks based at least in part on the first voltage being associated with satisfying the first voltage threshold, and
selecting the second sub-block comprises applying a second voltage to the subset of bit lines corresponding to the plurality of sub-blocks based at least in part on the second voltage being associated with satisfying the second voltage threshold.

13. The memory device of claim 12, wherein the memory device is configured to refrain from selecting the sub-block based at least in part on applying the first voltage to the plurality of sub-blocks.

14. The memory device of claim 1, wherein:
the stack of materials extends above a substrate in a first direction;
the bit line contact extends in a second direction perpendicular to the first direction; and
the plurality of bit lines extend at least partially through the stack of materials in the first direction, and each bit line of the subset of bit lines is coupled with the bit line contact within a respective contact region and is physically isolated from other bit lines of the subset of bit lines within other regions different from the respective contact region.

15. The memory device of claim 14, wherein each bit line comprises:
a first segment extending along a third direction within the stack of materials, the third direction perpendicular to the second direction; and
a second segment extending along the first direction within the stack of materials.

16. The memory device of claim 15, wherein:
a first bit line of the plurality of bit lines comprises the first segment at a first height above the substrate in the first direction, and a second bit line of the plurality of bit lines adjacent to the first bit line in the third direction comprises the first segment at a second height above the substrate in the first direction, and
the first height is different than the second height.

17. The memory device of claim 1, further comprising:
a plurality of word lines each associated with a respective level of the stack of materials, wherein accessing a memory cell is based at least in part on accessing a word line of the plurality of word lines that is associated with a respective bit line of the plurality of bit lines.

18. The memory device of claim 1, further comprising:
a plurality of separation regions between the plurality of bit lines within the stack of materials, wherein each pair of adjacent bit lines is physically isolated from each other by a respective separation region of the plurality of separation regions.

19. A method, comprising:
forming a stack comprising a plurality of levels, each level comprising a conductive material or a dielectric material, wherein a first set of the levels comprises one or more first control blocks, a second set of the levels comprises one or more second control blocks, and a third set of the levels comprise a logically addressable block, and wherein forming the plurality of levels comprises:
forming one or more levels with a different material configuration from the plurality of levels;
forming a cavity extending through the stack;
forming a bit line contact based at least in part on depositing conductive material within the cavity; and
forming a plurality of bit lines extending through the stack and coupled with supporting circuitry via the bit line contact, wherein each bit line of a subset of the plurality of bit lines corresponds to a sub-block of a plurality of sub-blocks and each bit line of the subset of bit lines is associated with a different voltage threshold based at least in part on each bit line of the subset of bit lines being associated with the one or more levels.

20. The method of claim 19, wherein forming the plurality of levels comprises:
depositing the dielectric material in an alternating pattern with the conductive material to form the plurality of levels, wherein forming the one or more levels comprises:
depositing a dielectric material at the one or more levels.

21. The method of claim 19, wherein forming the plurality of levels comprises:
depositing the dielectric material in an alternating pattern with the conductive material of a first thickness to form the plurality of levels, wherein forming the one or more levels comprises:
depositing a conductive material of a second thickness at the one or more levels.

22. The method of claim 19, wherein forming the plurality of levels comprises:
depositing the dielectric material in an alternating pattern with the conductive material to form the plurality of levels, wherein forming the one or more levels comprises:
doping a material at the one or more levels with a dopant.

23. The method of claim 19, further comprising:
forming a plurality of memory cells at the plurality of levels in the stack, wherein at least a portion of the plurality of memory cells are organized into a block that is divided into the plurality of sub-blocks, each sub-block being independently accessible from other sub-blocks of the plurality of sub-blocks.

24. The method of claim 19, further comprising:
forming layers of materials within the cavity, the layers of materials comprising a first protective liner, a storage material, and a second protective liner,
wherein forming the bit line contact and the plurality of bit lines is based at least in part on forming the layers of materials within the cavity.

25. The method of claim 19, wherein forming the plurality of bit lines comprises:
depositing the conductive material along a bottom wall of the cavity and along sidewalls of the cavity; and
etching, back at least in part on a mask, alternating regions of the conductive material to form a plurality of U-shaped strips of the conductive material that extend along the bottom wall of the cavity and the sidewalls of the cavity, wherein each U-shaped strip is physically isolated from other U-shaped strips of the plurality of U-shaped strips.
